(19) United States
(12) Patent Application Publication
(10) Pub. No.: US 2014/0253165 A1
(43) Pub. Date: Sep. 11, 2014

(54) PROBE CARD

(71) Applicant: SAMSUNG ELECTRONICS CO., LTD., Suwon-si (KR)

(72) Inventors: Yu-Kyum KIM, Hwaseong-si (KR); Joon-Yeon KIM, Yongin-si (KR); Sung-Ho JOO, Seoul (KR)

(73) Assignee: SAMSUNG ELECTRONICS CO., LTD., Suwon-si (KR)

(21) Appl. No.: 14/198,750

(22) Filed: Mar. 6, 2014

(30) Foreign Application Priority Data
Mar. 8, 2013 (KR) 10-2013-0024753

(51) Int. Cl. G01R 1/073

(52) U.S. Cl. CPC G01R 1/07307
USPC 324/756.03

(57) ABSTRACT

A probe card includes a first circuit substrate electrically connected to a tester, the first circuit substrate having a first size, a second circuit substrate on a lower surface of the first circuit substrate and electrically connected to the first circuit substrate, the second circuit substrate having a second size smaller than the first size, a probe head under the second circuit substrate and electrically connected to the second circuit substrate, the probe head including a plurality of probes in contact with terminals of a device under test (DUT), and a probe holder under the first circuit substrate and supporting the probe head.

### CROSS-REFERENCE TO RELATED APPLICATION

Korean Patent Application No. 10-2013-0024753, filed on Mar. 8, 2013, in the Korean Intellectual Property Office, and entitled: “Probe Card,” is incorporated by reference herein in its entirety.

### BACKGROUND

1. Field

Example embodiments relate to a probe card. More particularly, example embodiments relate to a probe card for testing integrated circuits (ICs) on a wafer.

2. Description of the Related Art

A probe card may be installed in a prober and electrically connected to a test head on the prober through cables to test a plurality of semiconductor chips on a wafer.

### SUMMARY

Example embodiments provide a probe card capable of improving signal branch characteristics.

According to example embodiments, a probe card includes a first circuit substrate to be electrically connected to a tester and having a first size, a second circuit substrate provided on a lower surface of the first circuit substrate, electrically connected to the first circuit substrate and having a second size smaller than the first size, a probe head provided under the second circuit substrate, electrically connected to the second circuit substrate and a plurality of probes that make contact with terminals of DUT, and a probe holder provided under the first circuit substrate and supporting the probe head.

In example embodiments, the second circuit substrate may be surrounded by the probe holder.

In example embodiments, the first circuit substrate may have a first thickness and the second circuit substrate may have a second thickness smaller than the first thickness.

In example embodiments, the second circuit substrate may be adhered to the lower surface of the first circuit substrate.

In example embodiments, the lowermost wiring layer of the first circuit substrate may include a first blind via and the uppermost wiring layer of the second circuit substrate may include a second blind via that is connected to the first blind via.

In example embodiments, the probe card may further include an interposer interposed between the second circuit substrate and the probe head to electrically connect the second circuit substrate to the probe head.

In example embodiments, the probe head may include a space transformer, the space transformer having traces that are electrically connected to the probes.

In example embodiments, the space transformer may be supported on an inner wall of the probe holder.

In example embodiments, the probe card may further include a stiffener provided on an upper surface of the first circuit substrate and supporting the first circuit substrate.

In example embodiments, each of the first and second circuit substrates may include a channel transmission branch line to branch a test channel from the tester.

In example embodiments, the first and second circuit substrates may further a plurality of stacked wiring layers respectively.

In example embodiments, the wiring layer may include a trace and a via that form a channel transmission line.

According to example embodiments, a probe card includes a first circuit substrate electrically connected to a tester, the first circuit substrate having a first size, a second circuit substrate on a lower surface of the first circuit substrate and electrically connected to the first circuit substrate, the second circuit substrate having a second size smaller than the first size, a probe head under the second circuit substrate and electrically connected to the second circuit substrate, the probe head including a plurality of probes in contact with terminals of a device under test (DUT), and a probe holder on the lower surface of the first circuit substrate, the probe holder extending from the first circuit substrate downwardly and supporting the probe head.

The second circuit substrate and the probe holder may be on a same surface, the second circuit substrate being surrounded by the probe holder.

The second circuit substrate may be between the first circuit substrate and the probe head.

The second circuit substrate may be directly on the first circuit substrate, the first and second circuit substrates being connected to each other by respective blind vias.

The probe head may include a space transformer, the probe holder being connected to the space transformer to support the probe head.

### BRIEF DESCRIPTION OF THE DRAWINGS

Features will become apparent to those of ordinary skill in the art by describing in detail exemplary embodiments with reference to the attached drawings, in which:

FIG. 1 illustrates a cross-sectional view of a probe card in accordance with example embodiments.

FIG. 2 illustrates a block diagram of a test system including the probe card of FIG. 1.

FIG. 3 illustrates a perspective view of first and second circuit boards in the probe card of FIG. 1.

FIG. 4 illustrates an enlarged view of portion A in FIG. 1.

### DETAILED DESCRIPTION

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

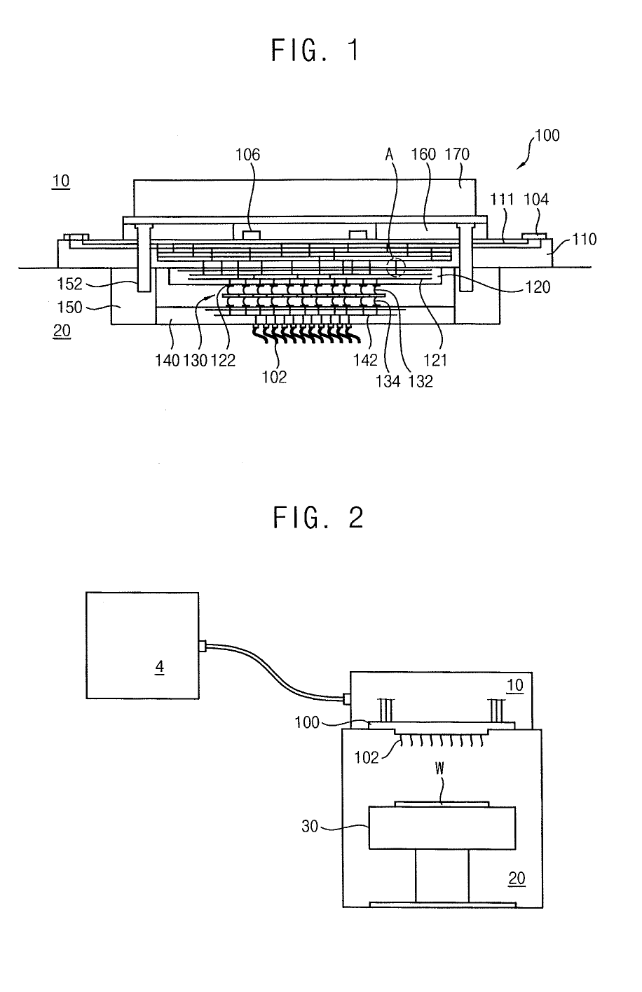

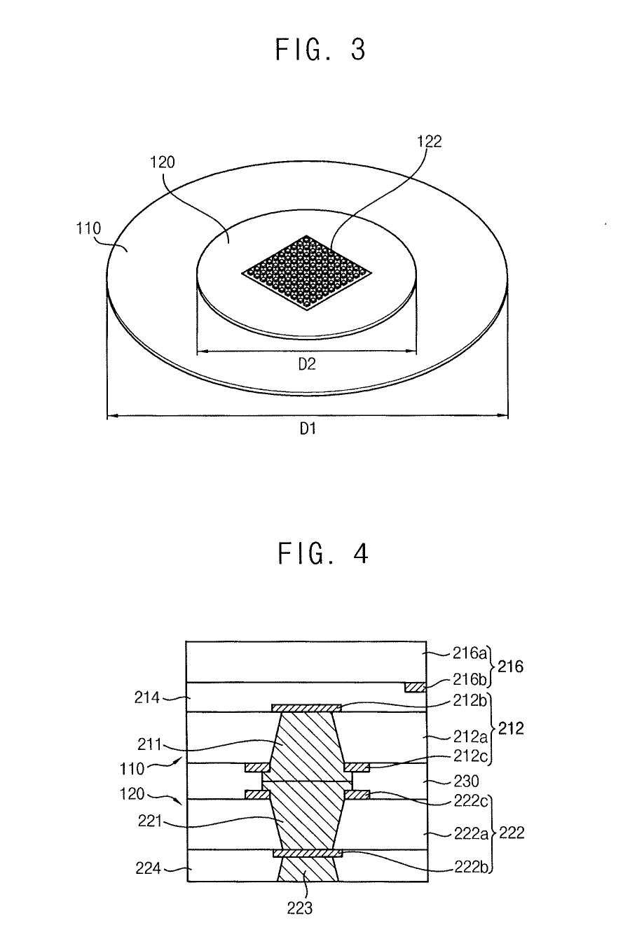

FIG. 1 illustrates a cross-sectional view of a probe card in accordance with example embodiments. FIG. 2 illustrates a block diagram of a test system including the probe card of FIG. 1. FIG. 3 illustrates a perspective view of first and second circuit boards of the probe card in FIG. 1. FIG. 4 illustrates an enlarged view of portion A in FIG. 1.

Referring to FIGS. 1 to 4, a probe card 100 may include a first circuit board 110 having a first size, a second circuit board 120 disposed on a lower surface of the first circuit board 110 and having a second size smaller than the first size, a probe head disposed under the second circuit board 120 and including a plurality of probes 102, and a probe holder 150 disposed under the first circuit board 110 and supporting the probe head.

In example embodiments, the probe card 100 may be used to test a DUT (Device Under Test) on a semiconductor wafer W. The probe card 100 may be installed in a prober 20 and connected to a tester 4 through a test head 10. A stage 30 of the prober 20 may be movable to contact the wafer W being tested with the probes 102 on the probe card 100.

Test data may be generated by a test system controller of the tester 4 and transmitted to the DUT on the wafer W through the test head 10, the probe card 100 and the probe 102. Test results may be provided from the DUTs through the probe card 100 to the test head 10.

The test data from the tester 4 may be divided into individual test channels in the test head 10 and each channel may be connected to the probe card 100. Then, the probe card 100 may connect each channel to a separate one of the probes 102.

As illustrated in FIG. 1, the first circuit substrate 110 may be detachably mounted on the probe holder 150 in an upper portion of the prober 20. The second circuit substrate 120 may be provided on the lower surface of the first circuit substrate 110, i.e., on a surface of the first circuit substrate 110 facing the probes 102. The second circuit substrate 120 may be electrically connected to the first circuit substrate 110.

The first circuit substrate 110 may include first channel transmission lines 111 for transferring a test signal. The second circuit substrate 120 may include second channel transmission lines 121 for transferring the test signal. As described in detail below, the first channel transmission lines 111 may be electrically connected to the second channel transmission lines 121 through a connection member, e.g., a conductive via.

Cable connectors 104 may be provided on an upper surface of the first circuit substrate 110. The cable connectors 104 may be arranged along a peripheral region of the first circuit substrate 120. The cables of the test head 10 may be inserted into cable connectors 104, respectively. For example, the cable connector 104 may be a ZIF (zero insertion force) connector. Alternatively, the cable connector 104 may be another type of connector, e.g., a non-ZIF flexible cable connector, a conductive elastomer bump, etc. Accordingly, a signal from the connector 104 may be horizontally distributed to connection pads 122 on a lower surface of the second circuit substrate 120 through the first and second channel transmission lines 111 and 121.

The probe head may be provided under the second circuit substrate 120, e.g., the second circuit substrate 120 may be between the first circuit substrate 110 and the probe head. The probe head may be electrically connected to the second circuit substrate 120 and include a plurality of the probes 102 that make contact with terminals of the DUT. The probe head may include a space transformer 140. The space transformer 140 may have traces 142 that are electrically connected to the probes 102.

An interposer 130 may be interposed between the second circuit substrate 120 and the probe head to electrically connect the second circuit substrate 120 to the probe head. For example, first spring contacts 132 may be provided on an upper surface of the interposer 130 and second spring contacts 134 may be provided on a lower surface of the interposer 130. The first spring contacts 132 may make contact with the connection pads 122 of the second circuit substrate 120, respectively. The second spring contacts 134 may make contact with pads forming a LGA (Land Grid Array) on an upper surface of the space transformer 140.

The probes 102 may be provided on a lower surface of the space transformer 140. The traces 142 of the space transformer 140 may connect the pads of the LGA and the probes 102. For example, a substrate of the space transformer 140 may include multi-layered ceramic.

In example embodiments, the probe holder 150 may be provided under the first circuit substrate 110 to support the probe head. The probe holder 150 may be fixed on the lower surface of the first circuit substrate 110, e.g., the probe holder 150 and the second circuit substrate 120 may be directly on a same surface of the first circuit substrate 110. The probe holder 150 may be provided to contact and surround, e.g., completely surround, an outer surface of the space transformer 140. Accordingly, the space transformer 140 may be supported on an inner wall of the probe holder 150. Although it is not illustrated in the figures, supporting members, e.g., a compensating plate (stiffener), a plate spring, and so on, may be provided between the probe holder 150 and the space transformer 140 to support the spacer transformer 140.

The second circuit substrate 120 may be disposed within the inner wall of the probe holder 150. For example, as illustrated in FIG. 1, the probe holder 150 may extend from the lower surface of the first circuit substrate 110 to contact edges of the space transformer 140, e.g., lowermost surfaces of the probe holder 150 and space transformer 140 may be substantially level. As such, a space may be defined between the lower surface of the first circuit substrate 110 and the space transformer 140, and framed by the probe holder 150, as illustrated in FIG. 1. The second circuit substrate 120 may be disposed in that space and on the lower surface of the first circuit substrate 110.

A stiffener 160 may be provided on the upper surface of the first circuit board 110. A circuit board 170 may be arranged on the stiffener 160. The stiffener 160 may support electrical components including the first circuit substrate 110. The stiffener 160 and the probe holder 150 may be fixed to each other via a fixing member, e.g., screws 152, with the first circuit substrate 110 interposed between the stiffener 160 and the probe holder 150.

Electrical components 106, e.g., a capacitor, may be provided on the upper surface of the first circuit substrate 110. The electrical components 106 may be provided within an opening of the stiffener 160. Although it is not illustrated in the figures, electrical components, a capacitor, may be provided on the space transformer 140.

As illustrated in FIGS. 3 and 4, the second circuit substrate 120 may be adhered to the lower surface of the first circuit substrate 110. The second circuit substrate 120 may be adhered to the first circuit substrate 110 by an adhesive layer 230. Alternatively, the second circuit substrate 120 may be adhered to the upper surface of the first circuit substrate 110, or both upper and lower surfaces of the first circuit substrate 110.

The first circuit substrate 110 may have the first size, and the second circuit substrate 120 may have the second size smaller than the first size. For example, the first and second circuit substrates 110 and 120 may have a circular plate shape respectively. The first circuit substrate 110 may have a first diameter (D1) and the second circuit substrate 120 may have a second diameter (D2) smaller than the first diameter (D1). For example, the first diameter (D1) may be about 480 mm and the second diameter (D2) may be about 330 mm.

The first circuit substrate 110 may have a first thickness, and the second circuit substrate 120 may have a second thickness smaller than the first thickness. For example, the first thickness may range from about 5.0 mm to about 6.5 mm, and the second thickness may range from about 2 mm to about 3 mm.

For example, the first circuit substrate 110 may include a plurality of stacked wiring layers. A first wiring layer 212 may include a first insulating layer 212a and a first wiring 212b, 212c. A second wiring layer 216 may include a second insulating layer 216a and a second wiring 216b. The first wiring layer 212 may be adhered to the second wiring layer 216 by a first adhesive layer 214. The first circuit substrate 110 may include 50 to 80 wiring layers.

The second circuit substrate 120 may include a plurality of stacked wiring layers. A third wiring layer 222 may include a third insulating layer 222a and a third wiring 222b, 222c. The third wiring layer 222 may be adhered to a fourth wiring layer (not illustrated) by a second adhesive layer 224. The second circuit substrate 110 may include 20 to 40 wiring layers. The number of wiring layers in the first and second circuit substrates 110 and 120 may be determined in consideration of the number of the channels, the thickness of the first and second circuit substrates, etc.

The first circuit substrate 110 may include a plurality of vias that penetrate the wiring layers 212 and 216 to be electrically connected to the wirings 212b and 216b. The wirings and the vias may form the first channel transmission line 111.

The second circuit substrate 120 may include a plurality of vias that penetrate the wiring layers 222 to be electrically connected to the wirings 222b. The wirings and the vias may form the second channel transmission line 121.

In example embodiments, the first channel transmission line 111 may be electrically connected to the second channel transmission line 121 by a connection member, e.g., a conductive via. The first channel transmission line 111 may be electrically connected to the second channel transmission line 121 by the blind vias 211 and 221.

The lowermost wiring layer 212 of the first circuit substrate 110 may include the first blind via 211 in a blind via hole (BVH). The upper most wiring layer 222 of the second circuit substrate 120 may include the second blind via 221 in a BVH. The first blind via 211 may contact, e.g., be in fluid communication with, the second blind via 221. Alternatively, the first blind via 211 may be connected to the second blind via 221 by a connection member, e.g., a bump. Accordingly, the first circuit substrate 110 and the second circuit substrate 120 may be adhered to each other by blind vias.

Because the second circuit substrate 120 may be adhered to the lower surface of the first circuit substrate 110, the number of the stacked wiring layers in the first circuit substrate 110 may be increased while the height, i.e., distance, of lower surface of the first circuit substrate 110 from the upper surface of the prober 20 may not be changed. Thus, a height of the probe card mounted on the prober 20 may be maintained and the number of the stacked wiring layers may be increased, thereby improving signal branch characteristics.

By way of summary and review, a probe card may include a first circuit substrate and a second circuit substrate adhered to a lower surface of the first circuit substrate and electrically connected to the first circuit substrate. A distance of the first circuit substrate from an upper surface of a prober may not be changed, while a number of stacked wiring layers in the first circuit substrate may be increased, thereby maximizing signal branches. Accordingly, a distance of a lowermost surface of the probe card, i.e., the lowermost surface of the second circuit substrate, mounted on the prober may be constant, and the number of the stacked wiring layers may be increased, thereby improving signal branch characteristics.

In contrast, in a conventional probe card, there is a limit to increase a height of a circuit substrate due to an interference with the test head. Accordingly, the number of stacked wiring layers in the circuit substrate may not be increased, thereby deteriorating signal branch characteristics.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A probe card, comprising:
a first circuit substrate to be electrically connected to a tester, the first circuit substrate having a first size;
a second circuit substrate on a lower surface of the first circuit substrate and electrically connected to the first circuit substrate, the second circuit substrate having a second size smaller than the first size;
a probe head under the second circuit substrate and electrically connected to the second circuit substrate, the probe head including a plurality of probes to be in contact with terminals of a device under test (DUT); and
a probe holder under the first circuit substrate and supporting the probe head.

2. The probe card as claimed in claim 1, wherein the second circuit substrate is surrounded by the probe holder.

3. The probe card as claimed in claim 1, wherein the first circuit substrate has a first thickness and the second circuit substrate has a second thickness smaller than the first thickness.

4. The probe card as claimed in claim 1, wherein the second circuit substrate contacts the lower surface of the first circuit substrate.

5. The probe card as claimed in claim 4, wherein a lowermost wiring layer of the first circuit substrate includes a first blind via and an uppermost wiring layer of the second circuit substrate includes a second blind via connected to the first blind via.

6. The probe card as claimed in claim 1, further comprising an interposer between the second circuit substrate and the probe head, the interposer electrically connecting the second circuit substrate to the probe head.

7. The probe card as claimed in claim 6, wherein the probe head includes a space transformer, the space transformer having traces electrically connected to the probes.

8. The probe card as claimed in claim 7, wherein the space transformer is supported on an inner wall of the probe holder.

9. The probe card as claimed in claim 1, further comprising a stiffener on an upper surface of the first circuit substrate and supporting the first circuit substrate.

10. The probe card as claimed in claim 1, wherein each of the first and second circuit substrates includes a channel transmission branch line branching a test channel from the tester.

11. The probe card as claimed in claim 1, wherein each of the first and second circuit substrates includes a plurality of stacked wiring layers.

12. The probe card as claimed in claim 11, wherein the wiring layers includes at least one trace and one via defining a channel transmission line.

13. A probe card, comprising:
a first circuit substrate to be electrically connected to a tester, the first circuit substrate having a first size;
a second circuit substrate on a lower surface of the first circuit substrate and electrically connected to the first circuit substrate, the second circuit substrate having a second size smaller than the first size;
a probe head under the second circuit substrate and electrically connected to the second circuit substrate, the probe head including a plurality of probes to be in contact with terminals of a device under test (DUT); and
a probe holder on the lower surface of the first circuit substrate, the probe holder extending from the first circuit substrate downwardly and supporting the probe head.

14. The probe card as claimed in claim 13, wherein the second circuit substrate and the probe holder are on a same surface, the second circuit substrate being surrounded by the probe holder.

15. The probe card as claimed in claim 14, wherein the second circuit substrate is between the first circuit substrate and the probe head.

16. The probe card as claimed in claim 14, wherein the second circuit substrate is directly on the first circuit substrate, the first and second circuit substrates being connected to each other by respective blind vias.

17. The probe card as claimed in claim 14, wherein the probe head includes a space transformer, the probe holder being connected to the space transformer to support the probe head.
